(19) United States
(12) Patent Application Publication
(10) Pub. No.: US 2022/0121927 A1
(43) Pub. Date: Apr. 21, 2022

(54) PROVIDING NEURAL NETWORKS

(71) Applicant: Arm Limited, Cambridge (GB)

(72) Inventor: Mark John O'CONNOR, Luebeck (DE)

(21) Appl. No.: 17/076,392

(22) Filed: Oct. 21, 2020

(51) Int. Cl. G06N 3/08; G06N 3/04; G06N 3/063; G06K 9/62; G06F 11/34

(52) U.S. Cl. CPC G06N 3/08; G06N 3/0454; G06F 11/3409; G06K 9/6256; G06N 3/063

(57) ABSTRACT

A computer-implemented method of providing a group of neural networks for processing data includes: identifying a group of neural networks including a main neural network and one or more sub-neural networks, each neural network comprising a plurality of parameters and wherein one or more of the parameters of each sub-neural network are shared by the sub-neural network and the main neural network; inputting training data into each neural network, and adjusting the parameters of each neural network; computing a performance score for each neural network using the adjusted parameters; generating a combined score for the group of neural networks by combining the performance score, with a value of a loss function computed for each neural network using the adjusted parameters; repeating the identifying and the inputting and the adjusting and the computing and the generating; and selecting a group of neural networks for processing data in the plurality of hardware environments based on the value of the combined score for each group of neural networks.

### BACKGROUND OF THE INVENTION

### Field of the Invention

The present disclosure relates to a computer-implemented method of providing a group of neural networks for processing data in a plurality of hardware environments. A related system, and a non-transitory computer-readable storage medium, are also disclosed. A computer-implemented method of identifying a neural network for processing data in a hardware environment, and a related device, and a related non-transitory computer-readable storage medium, are also disclosed.

### Description of the Related Technology

Neural networks are employed in a wide range of applications such as image classification, speech recognition, character recognition, image analysis, natural language processing, gesture recognition and so forth. Many different types of neural network such as Convolutional Neural Networks “CNN”, Recurrent Neural Networks “RNN”, Generative Adversarial Networks “GAN”, and Autoencoders have been developed and tailored to such applications.

Neurons are the basic unit of a neural network. A neuron has one or more inputs and generates an output based on the input(s). The value of data applied to each input(s) is typically multiplied by a “weight” and the result is summed. The summed result is input into an “activation function” in order to determine the output of the neuron. The activation function has a “bias” that controls the output of the neuron by providing a threshold to the neuron's activation. The neurons are typically arranged in layers, which may include an input layer, an output layer, and one or more hidden layers arranged between the input layer and the output layer. The weights determine the strength of the connections between the neurons in the network. The weights, the biases, and the neuron connections are examples of “trainable parameters” of the neural network that are “learnt”, or in other words, capable of being trained, during a neural network “training” process. Another example of a trainable parameter of a neural network, found particularly in neural networks that include a normalization layer, is the (batch) normalization parameter(s). During training, the (batch) normalization parameter(s) are learnt from the statistics of data flowing through the normalization layer.

A neural network also includes “hyperparameters” that are used to control the neural network training process. Depending on the type of neural network concerned, the hyperparameters may for example include one or more of: a learning rate, a decay rate, momentum, a learning schedule and a batch size. The learning rate controls the magnitude of the weight adjustments that are made during training. The batch size is defined herein as the number of data points used to train a neural network model in each iteration.

The process of training a neural network includes adjusting the weights that connect the neurons in the neural network, as well as adjusting the biases of activation functions controlling the outputs of the neurons. There are two main approaches to training: supervised learning and unsupervised learning. Supervised learning involves providing a neural network with a training dataset that includes input data and corresponding output data. The training dataset is representative of the input data that the neural network will likely be used to analyze after training. During supervised learning the weights and the biases are automatically adjusted such that when presented with the input data, the neural network accurately provides the corresponding output data. The input data is said to be “labelled” or “classified” with the corresponding output data. In unsupervised learning the neural network decides itself how to classify or generate another type of prediction from a training dataset that includes un-labelled input data based on common features in the input data by likewise automatically adjusting the weights, and the biases. Semi-supervised learning is another approach to training wherein the training dataset includes a combination of labelled and un-labelled data. Typically, the training dataset includes a minor portion of labelled data. During training the weights and biases of the neural network are automatically adjusted using guidance from the labelled data.

Whichever training process is used, training a neural network typically involves inputting a large training dataset, and making numerous iterations of adjustments to the neural network parameters until the trained neural network provides an accurate output. As may be appreciated, significant processing resources are typically required in order to perform this optimization process. Training is usually performed using a Graphics Processing Unit “GPU” or a dedicated neural processor such as a Neural Processing Unit “NPU” or a Tensor Processing Unit “TPU”. Training therefore typically employs a centralized approach wherein cloud-based or mainframe-based neural processors are used to train a neural network. Following its training with the training dataset, the trained neural network may be deployed to a device for analyzing new data; a process termed “inference”. Inference may be performed by a Central Processing Unit “CPU”, a GPU, an NPU, on a server, or in the cloud.

However, there remains a need to provide improved neural networks.

### SUMMARY

According to a first aspect of the disclosure, there is provided a computer-implemented method of providing a group of neural networks for processing data in a plurality of hardware environments. The method comprises:
identifying a group of neural networks including a main neural network and one or more sub-neural networks, each neural network in the group of neural networks comprising a plurality of parameters and wherein one or more of the parameters of each sub-neural network are shared by the sub-neural network and the main neural network;
inputting training data into each neural network in the group of neural networks, and adjusting the parameters of each neural network using an objective function computed based on a difference between output data generated at an output of each neural network, and expected output data;
computing a performance score for each neural network in the group of neural networks using the adjusted parameters, the performance score representing a performance of each neural network in a respective hardware environment;
generating a combined score for the group of neural networks by combining the performance score of each neural network in the group of neural networks, with a value of a loss function computed for each neural network in the group of neural networks using the adjusted parameters;
repeating the identifying and the inputting and the adjusting and the computing and the generating, for two or more iterations; and
selecting from the plurality of groups of neural networks generated by the repeating, a group of neural networks for processing data in the plurality of hardware environments based on the value of the combined score for each group of neural networks.

According to a second aspect of the disclosure, there is provided a computer-implemented method of identifying a neural network for processing data in a hardware environment. The method comprises:
i) receiving a group of neural networks provided according to the method of the first aspect of the disclosure, the group of neural networks including metadata representing a target hardware environment and/or a hardware requirement, of each neural network in the group of neural networks; and
selecting, based on the metadata, a neural network from the group of neural networks to process data; or
ii) receiving a group of neural networks provided according to the above method; and
computing a performance score for one or more neural networks in the group of neural networks based on an output of the respective neural network generated in response to inputting test data into the respective neural network and processing the test data with the respective neural network in the hardware environment; and
selecting a neural network from the group of neural networks to process data based on a value of the performance score.

A system, a device, and a non-transitory computer-readable storage medium are provided in accordance with other aspects of the disclosure. The functionality disclosed in relation to the computer-implemented method of the first aspect of the disclosure may also be implemented in the system, and in a non-transitory computer-readable storage medium, in a corresponding manner. The functionality disclosed in relation to the computer-implemented method of the second aspect of the disclosure may also be implemented in the device, and in a non-transitory computer-readable storage medium, in a corresponding manner.

Further aspects, features and advantages of the disclosure will become apparent from the following description of examples, which is made with reference to the accompanying drawings.

### BRIEF DESCRIPTION OF THE DRAWINGS

FIG. 1 is a schematic diagram illustrating an example neural network.

FIG. 2 is a schematic diagram illustrating an example neuron.

FIG. 3 is a flowchart illustrating an example of a computer-implemented method of providing a group of neural networks for processing data in a plurality of hardware environments, in accordance with some aspects of the present disclosure.

FIG. 4 is a schematic diagram illustrating an example of a system 500 for providing a group of neural networks for processing data in a plurality of hardware environments, in accordance with some aspects of the present disclosure.

FIG. 5 is a schematic diagram illustrating an example of a group of neural networks including a main neural network 100 and two sub-neural networks 200, 300, in accordance with some aspects of the present disclosure.

FIG. 6 is a schematic diagram illustrating an example of inputting S110 training data and adjusting S120 parameters of each neural network using an objective function 410, in accordance with some aspects of the present disclosure.

FIG. 7 is a schematic diagram illustrating an example of computing S130 a performance score 120, 220, 320 for a main neural network and for each of two sub-neural networks 200, 300 by inputting test data 430 to each neural network 100, 200, 300 in a simulation of a respective hardware environment 130, 230, 330, in accordance with some aspects of the present disclosure.

FIG. 8 is a flowchart illustrating an example of a computer-implemented method of identifying a neural network for processing data in a hardware environment, in accordance with some aspects of the present disclosure.

### DETAILED DESCRIPTION OF CERTAIN INVENTIVE EMBODIMENTS

Examples of the present disclosure are provided with reference to the following description and the figures. In this description, for the purposes of explanation, numerous specific details of certain examples are set forth. Reference in the specification to “an example”, “an implementation” or similar language means that a feature, structure, or characteristic described in connection with the example is included in at least that one example. It is also to be appreciated that features described in relation to one example may also be used in another example and that all features are not necessarily duplicated for the sake of brevity. For instance, features described in relation to one computer-implemented method may also be implemented in a non-transitory computer-readable storage medium, or in a system, in a corresponding manner. Features described in relation to another computer-implemented method may also be implemented in a non-transitory computer-readable storage medium, or in a device, in a corresponding manner.

In the present disclosure, reference is made to examples of a neural network in the form of a Deep Feed Forward neural network. It is however to be appreciated that the disclosed method is not limited to use with this particular neural network architecture, and that the method may be used with other neural network architectures, such as for example a CNN, a RNN, a GAN, an Autoencoder, and so forth. Reference is also made to operations in which the neural network processes input data in the form of image data, and uses the image data to generate output data in the form of a prediction or “classification”. It is to be appreciated that these example operations serve for the purpose of explanation only, and that the disclosed method is not limited to use in classifying image data. The disclosed method may be used to generate predictions based on input in general, and the method may process other forms of input data to image data, such as audio data, motion data, vibration data, video data, text data, numerical data, financial data, light detection and ranging “LiDAR” data, and so forth.

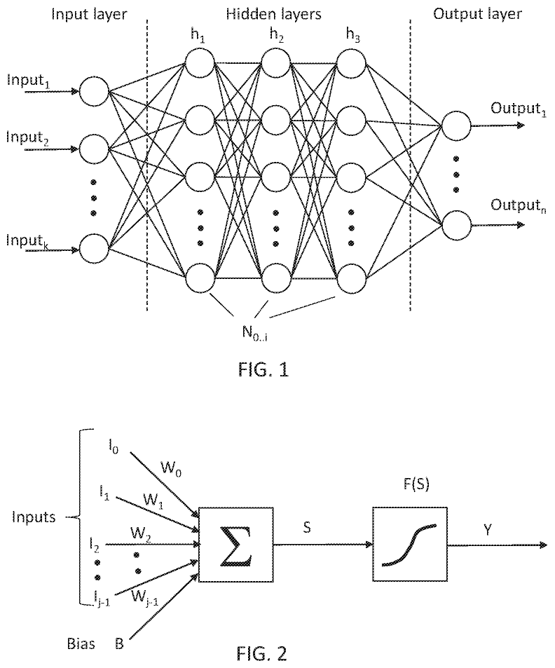

FIG. 1 is a schematic diagram illustrating an example neural network. The example neural network in FIG. 1 is a Deep Feed Forward neural network that includes neurons arranged in an Input layer, three Hidden layers h₁-h₃, and an Output layer. The example neural network in FIG. 1 receives input data in the form of numeric or binary input values at the inputs of neurons in its Input layer, Input₁-Inputₖ, processes the input values by means of the neurons in its hidden layers, h₁-h₃, and generates output data at the outputs of neurons in its Output layer, Outputs_{1 . . . n}. The input data may for instance represent image data, or audio data and so forth. Each neuron in the Input layer represents a portion of the input data, such as for example a pixel of an image. For some neural networks, the number of neurons in the Output layer depends on the number of predictions the neural network is programmed to perform. For regression tasks such as the prediction of a currency exchange rate this may be a single neuron. For a classification task such as classifying images as one of cat, dog, horse, etc. there is typically one neuron per classification class in the output layer.

As illustrated in FIG. 1, the neurons of the Input layer are coupled to the neurons of the first Hidden layer, h₁. The neurons of the Input layer pass the un-modified input data values at their inputs, Input₁-Inputₖ, to the inputs of the neurons of the first Hidden layer h₁. The input of each neuron in the first Hidden layer h₁ is therefore coupled to one or more neurons in the Input layer, and the output of each neuron in the first Hidden layer h₁ is coupled to the input of one or more neurons in the second Hidden layer h₂. Likewise, the input of each neuron in the second Hidden layer h₂ is coupled to the output of one or more neurons in the first Hidden layer h₁, and the output of each neuron in the second Hidden layer h₂ is coupled to the input of one or more neurons in the third Hidden layer h₃. The input of each neuron in the third Hidden layer h₃ is therefore coupled to the output of one or more neurons in the second Hidden layer h₂, and the output of each neuron in the third Hidden layer h₃ is coupled to one or more neurons in the Output layer.

FIG. 2 is a schematic diagram illustrating an example neuron. The example neuron illustrated in FIG. 2 may be used to provide the neurons in Hidden layers h₁-h₃ of FIG. 1, as well as the neurons in the output layer of FIG. 1. As mentioned above, the neurons of the Input layer typically pass the un-modified input data values at their inputs, Input₁-Inputₖ, to the inputs of the neurons of the first Hidden layer h₁. The example neuron in FIG. 2 includes a summing portion labelled with a sigma symbol, and an activation function labelled with an S-shaped symbol. In operation, data inputs I₀-Iⱼ₋₁ are multiplied by corresponding weights w₀-wⱼ₋₁ and summed, together with the bias value B. The intermediate output value S is inputted to the activation function F(S) to generate neuron output Y. The activation function acts as a mathematical gate and determines how strongly the neuron should be activated at its output Y based on its input value S. The activation function typically also normalizes its output Y, for example to a value of between 0 and 1, or between −1 and +1. Various activation functions may be used, such as a Sigmoid function, a Tan h function, a step function, Rectified Linear Unit “ReLU”, Softmax and Swish function.

Variations of the example Feed Forward Deep neural network described above with reference to FIG. 1 and FIG. 2 that are used in other types of neural networks may for instance include the use of different numbers of neurons, different numbers of layers, different types of layers, different connectivity between the neurons and the layers, and the use of layers and/or neurons with different activation functions to that exemplified above with reference to FIG. 1 and FIG. 2. For example, a convolutional neural network includes additional filter layers, and a recurrent neural network includes neurons that send feedback signals to each other. However, as described above, a feature common to neural networks is that they include multiple “neurons”, which are the basic unit of a neural network.

As outlined above, the process of training a neural network includes automatically adjusting the above-described weights that connect the neurons in the neural network, as well as the biases of activation functions controlling the outputs of the neurons. This is carried out by inputting a training dataset into the neural network and adjusting, or optimizing, the parameters of the neural network, based on a value of an objective function. In supervised learning, the neural network is presented with (training) input data that has a known classification. The input data might for instance include images of animals that have been classified with an animal “type”, such as cat, dog, horse, etc. The value of the objective function typically depends on the difference between the output of the neural network and the known classification. In supervised learning, the training process uses the value of the objective function to automatically adjust the weights and the biases so as to minimize the value of the objective function. This occurs when the output of the neural network accurately provides the known classification. The neural network may for example be presented with a variety of images corresponding to each class. The neural network analyzes each image and predicts its classification. The value of the objective function represents the difference between the predicted classification and the known classification, and is used to “backpropagate” adjustments to the weights and biases in the neural network such that the predicted classification is closer to the known classification. The adjustments are made by starting from the output layer and working backwards in the neural network until the input layer is reached. In the first training iteration the initial weights and biases, of the neurons are often randomized. The neural network then predicts the classification, which is essentially random. Backpropagation is then used to adjust the weights and the biases. The teaching process is terminated when the value of the objective function, which represents the difference, or error, between the predicted classification and the known classification, is within an acceptable range for the training data. In a later phase, the trained neural network is deployed and presented with new images without any classification. If the training process was successful, the trained neural network accurately predicts the classification of the new images.

Various algorithms are known for use in the backpropagation stage of training. Algorithms such as Stochastic Gradient Descent “SGD”, Momentum, Adam, Nadam, Adagrad, Adadelta, RMSProp, and Adamax “optimizers” have been developed specifically for this purpose. Essentially, the value of a loss function, such as the mean squared error, or the Huber loss, or the cross entropy, is determined based on a difference between the predicted classification and the known classification. The backpropagation algorithm uses the value of this loss function to adjust the weights and biases. In SGD, for example, the derivative of the loss function with respect to each weight is computed using the activation function and this is used to adjust each weight.

With reference to FIG. 1 and FIG. 2, therefore, training the neural network in FIG. 1 includes adjusting the weights w₀-wⱼ₋₁, and the bias value B applied to the exemplary neuron of FIG. 2, for the neurons in the hidden layers h₁-h₃ and in the Output layer. The training process is computationally complex and therefore cloud-based, or server-based, or mainframe-based processing systems that employ dedicated neural processors are typically employed. During training of the neural network in FIG. 1, the parameters of the neural network, or more specifically the weights and the biases, are adjusted via the aforementioned backpropagation procedure such that an objective function representing a difference between the known classification and the classification generated at Output₁-Outputₙ of the neural network in response to inputting training data into the student neural network, satisfies a stopping criterion. In other words, the training process is used to optimize the parameters of the neural network, or more specifically the weights and the biases. In supervised learning, the stopping criterion may be that the value of the objective function, i.e. the difference between the output data generated at Output₁-Outputₙ, and the label(s) of the input data, is within a predetermined margin. For example, if the input data includes images of cats, and if a definite classification of a cat is represented by a probability value of unity at Output₁, the stopping criterion might be that the for each input cat image the neural network generates a value of greater than 75% at Output₁. In unsupervised learning, a stopping criterion might be that a self-generated classification that is determined by the neural network itself based on commonalities in the input data, likewise generates a value of greater than 75% at Output₁. Alternative stopping criteria may also be used in a similar manner during training.

After a neural network such as that described with reference to FIG. 1 and FIG. 2 has been trained, the neural network may be deployed. Deployment may involve transferring the neural network to another computing device in order to perform inference. During inference, new data is inputted to the neural network and predictions are made thereupon. For example, the new input data may be classified by the neural network. The processing requirements of performing inference are significantly less than those required during training. This allows the neural network to be deployed to a variety of computing devices such as laptop computers, tablets, mobile phones and so forth. In order to further alleviate the processing requirements of the device on which the neural network is deployed, further optimization techniques may also be carried out that make further changes to the parameters of the neural network. Such techniques may take place prior to or after deployment of the neural network, and may include a process termed compression.

Compression is defined herein as pruning and/or quantization and/or weight clustering. Pruning a neural network is defined herein as the removal of one or more connections in a neural network. Pruning involves removing one or more neurons from the neural network, or removing one or more connections defined by the weights of the neural network. This may involve removing one or more of its weights entirely, or setting one or more of its weights to zero. Pruning permits a neural network to be processed faster due to the reduced number of connections, or due to the reduced computation time involved in processing zero value weights. Quantization of a neural network involves reducing a precision of one or more of its weights or biases. Quantization may involve reducing the number of bits that are used to represent the weights—for example from 32 to 16, or changing the representation of the weights from floating point to fixed point. Quantization permits the quantized weights to be processed faster, or by a less complex processor. Weight clustering in a neural network involves identifying groups of shared weight values in the neural network and storing a common weight for each group of shared weight value. Weight clustering permits the weights to be stored with less bits, and reduces the storage requirements of the weights as well as the amount of data transferred when processing the weights. Each of the above-mentioned compression techniques act to accelerate or otherwise alleviate the processing requirements of the neural network. Examples techniques for pruning, quantization and weight clustering are described in a document by Han, Song et al. (2016) entitled “Deep Compression: Compressing Deep Neural Networks with Pruning, Trained Quantization and Huffman Coding”, arXiv:1510.00149v5, published as a conference paper at ICLR 2016.

Inference may be performed in a plethora of hardware environments, and the performance of a neural network during inference may also be improved by taking the hardware environment into account when designing the neural network. For example, the ARM M-class processors such as the Arm Cortex-M55, the Arm Cortex-M7, and the Arm Cortex-M0, typically have a hard limit on the amount of SRAM available for intermediate values and are efficient at processing small neural networks. By contrast, the ARM A-class processors such as the Arm Cortex-A78, the Arm Cortex-A57, and the Arm Cortex-A55, typically accept larger neural networks and their multiple cores improve their efficiency at performing large matrix multiplications. By way of another example, many neural processing units “NPU”s have a very high computing throughput and prefer to trade computing throughput for memory. Neural networks that are designed for a particular hardware environment, such as these example processors, may have improved performance in that hardware environment than neural networks that are designed for a generic hardware environment. The performance may be measured in terms such as accuracy, latency and energy. These three competing measurements of performance are frequently traded-off against each other. However, at the time of designing a neural network, the neural network designer may not be fully aware of the specific hardware environment in which it will be used to perform inference. The neural network designer may therefore consider to design a neural network for a conservative target hardware environment, such as a CPU, or consider to design a neural network for each of multiple specific hardware environments. The former approach risks achieving sub-optimal latency because the device on which inference is performed may ultimately have superior processing capability than a CPU. The latter approach risks wasted efforts in designing and optimizing neural networks for hardware environments in which the neural network is never used. Both of these approaches may therefore result in sub-optimal neural network performance.

The inventor has found an improved method of providing neural networks for processing data in a plurality of hardware environments. The method may be used to provide neural networks such as the Deep Feed Forward neural network described above with reference to FIG. 1, or indeed neural networks with other architectures.

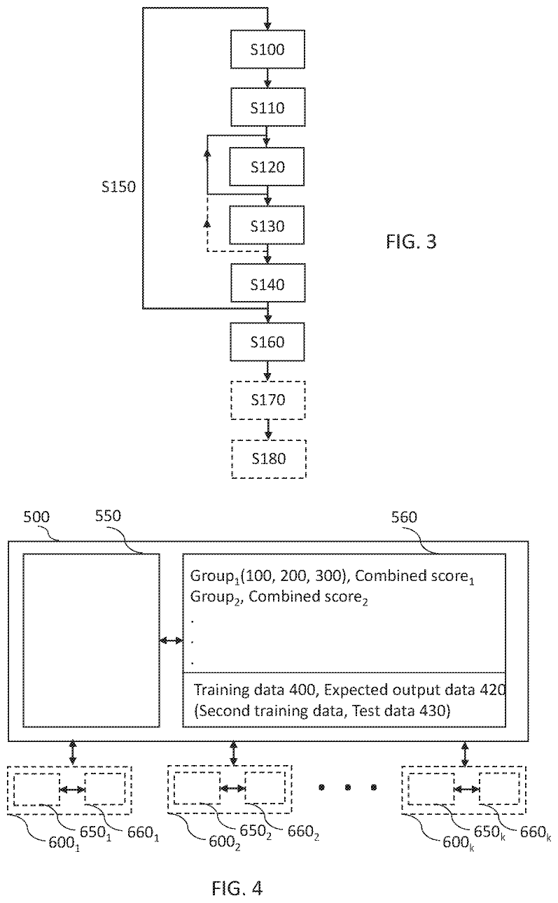

FIG. 3 is a flowchart illustrating an example of a computer-implemented method of providing a group of neural networks for processing data in a plurality of hardware environments, in accordance with some aspects of the present disclosure. The computer-implemented method includes:
identifying S100 a group of neural networks including a main neural network 100 and one or more sub-neural networks 200, 300, each neural network 100, 200, 300 in the group of neural networks comprising a plurality of parameters and wherein one or more of the parameters of each sub-neural network are shared by the sub-neural network and the main neural network 100;
inputting S110 training data 400 into each neural network 100, 200, 300 in the group of neural networks, and adjusting S120 the parameters of each neural network 100, 200, 300 using an objective function 410 computed based on a difference between output data generated at an output 110, 210, 310 of each neural network 100, 200, 300, and expected output data 420;
computing S130 a performance score 120, 220, 320 for each neural network 100, 200, 300 in the group of neural networks using the adjusted parameters, the performance score representing a performance of each neural network 100, 200, 300 in a respective hardware environment 130, 230, 330;
generating S140 a combined score for the group of neural networks by combining the performance score 120, 220, 320 of each neural network 100, 200, 300 in the group of neural networks, with a value of a loss function computed for each neural network 100, 200, 300 in the group of neural networks using the adjusted parameters;
repeating S150 the identifying S100 and the inputting S110 and the adjusting S120 and the computing S130 and the generating S140, for two or more iterations; and
selecting S160 from the plurality of groups of neural networks generated by the repeating S150, a group of neural networks for processing data in the plurality of hardware environments 130, 230, 330 based on the value of the combined score for each group of neural networks.

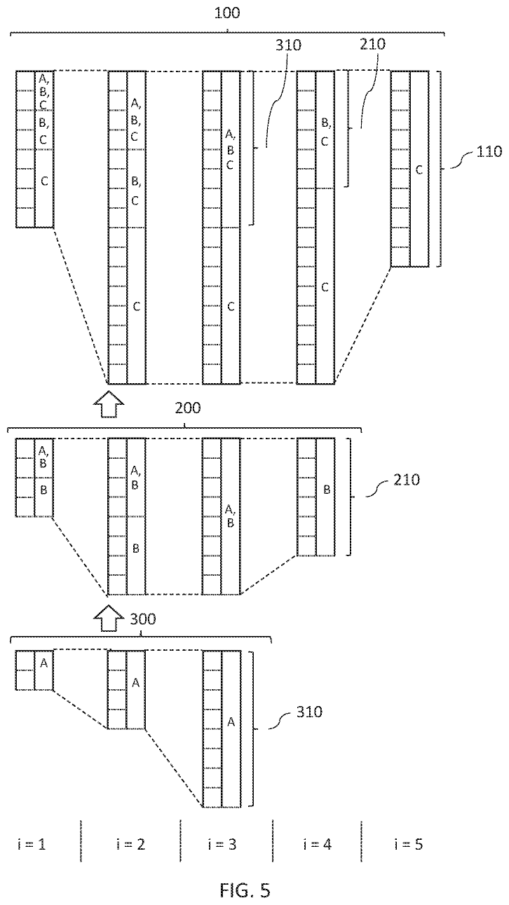

Aspects of the above method are described in detail below with further reference to FIG. 4-FIG. 7. A corresponding system for implementing the above method is also provided. Thereto, FIG. 4 is a schematic diagram illustrating an example of a system 500 for providing a group of neural networks for processing data in a plurality of hardware environments, in accordance with some aspects of the present disclosure. The system 500 includes a first processing system 550 comprising one or more processors configured to carry out a method comprising:
identifying S100 a group of neural networks including a main neural network 100 and one or more sub-neural networks 200, 300, each neural network 100, 200, 300 in the group of neural networks comprising a plurality of parameters and wherein one or more of the parameters of each sub-neural network are shared by the sub-neural network and the main neural network 100;
inputting S110 training data 400 into each neural network 100, 200, 300 in the group of neural networks, and adjusting S120 the parameters of each neural network 100, 200, 300 using an objective function 410 computed based on a difference between output data generated at an output 110, 210, 310 of each neural network 100, 200, 300, and expected output data 420;
computing S130 a performance score 120, 220, 320 for each neural network 100, 200, 300 in the group of neural networks using the adjusted parameters, the performance score representing a performance of each neural network 100, 200, 300 in a respective hardware environment 130, 230, 330;
generating S140 a combined score for the group of neural networks by combining the performance score 120, 220, 320 of each neural network 100, 200, 300 in the group of neural networks, with a value of a loss function computed for each neural network 100, 200, 300 in the group of neural networks using the adjusted parameters;
repeating S150 the identifying S100 and the inputting S110 and the adjusting S120 and the computing S130 and the generating S140, for two or more iterations; and
selecting S160 from the plurality of groups of neural networks generated by the repeating S150, a group of neural networks for processing data in the plurality of hardware environments 130, 230, 330 based on the value of the combined score for each group of neural networks.

The system 500 may also include further features that are described below with reference to the method illustrated in FIG. 3. For the sake of brevity, a description of each of these features is not duplicated for the system as well as for the method.

The computer-implemented method illustrated in FIG. 3 starts with operation S100, and wherein a group of neural networks including a main neural network 100 and one or more sub-neural networks 200, 300 are identified. Each neural network 100, 200, 300 in the group of neural networks comprises a plurality of parameters and wherein one or more of the parameters of each sub-neural network are shared by the sub-neural network and the main neural network 100.

FIG. 5 is a schematic diagram illustrating an example of a group of neural networks including a main neural network 100 and two sub-neural networks 200, 300, in accordance with some aspects of the present disclosure. With reference to the upper portion of FIG. 5, the example main neural network 100 includes multiple neurons (indicated by the square boxes) that are arranged in five layers labelled i=1 . . . 5. The layer i=1 represents an input layer of the main neural network 100, the layer i=5 represents an output layer of the main neural network 100, and the layers i=2 . . . 4 represent hidden layers of the main neural network 100. Each of the neurons in layers i=2 . . . 5 in FIG. 5 may for example be provided by the neuron illustrated in FIG. 2. Thus, multiple weights (not illustrated in FIG. 5) provide connections between the layers i=1 to i=2, and between the layers i=2 to i=3, and between the layers i=3 to i=4, and between the layers i=4 to i=5 of the main neural network 100, and each of the neurons in layers i=2 . . . 5 of the main neural network 100 in FIG. 5 also includes a bias value, as described above with reference to the neuron in FIG. 2. The main neural network 100 illustrated in FIG. 5 includes an output 110 in layer i=5, which may for example comprise a vector or an array of one or more values.

The central portion of FIG. 5 illustrates a sub-neural network 200, and the lower portion of FIG. 5 illustrates another sub-neural network 300. The sub-neural network 200 includes four layers, denoted i=1 . . . 4, and the sub-neural network 300 include three layers, denoted i=1 . . . 3. As with the main neural network 100, the inputs to the sub-neural networks 200 and 300 are in layer i=1. The outputs of sub-neural networks 200, 300 are labelled 210, 310 respectively. The sub-neural network 200 includes two hidden layers in layers i=2 and i=3, and the sub-neural network 300 includes one hidden layer in layer i=2. As with the main neural network, each of the sub-neural networks 200, 300 include neurons (indicated by the square boxes), and multiple weights (not illustrated in FIG. 5).

The neurons in FIG. 5 are labelled with references “A”, “B”, “C”. The neurons of the main neural network are identified with reference “C”, the neurons of the sub-neural network 200 are identified with reference “B”, and the neurons of the sub-neural network 300 are identified with reference “A”. As can be seen in the example main neural network 100 illustrated in the upper portion of FIG. 5, all of the neurons of the sub-neural network 200, i.e. all the neurons labelled B, are shared by sub-neural network 200 and the main neural network 100. Whilst the individual connections between the neurons in FIG. 5 are not indicated, the sharing of neurons in this manner is also intended to indicate that all of the parameters of the sub-neural network 200, i.e. the trainable parameters, are shared by the sub-neural network 200 and the main neural network 100. In the example main neural network 100 illustrated in FIG. 5 it can also be seen that all of the neurons of sub-neural network 300, i.e. the neurons labelled A, are also shared by the sub-neural network 300 and the main neural network 100. Thus, all of the parameters of the sub-neural network 300, are shared by the sub-neural network 300 and the main neural network 100. In the example group of neural networks illustrated in FIG. 5, it may be said that the parameters of each sub-neural network 200, 300, represent a subset of the parameters of the main neural network 100.

It can also be seen from the example main neural network 100 in FIG. 5, that all of the neurons of the sub-neural network 300, i.e. the neurons labelled A, are shared by the sub-neural network 300 and sub-neural network 200. Thus, all of the parameters of the sub-neural network 300, are shared by the sub-neural network 300 and the sub-neural network 200. Thus, the group of neural networks illustrated in the upper portion of FIG. 5 includes a main neural network 100 and two sub-neural networks 200, 300 wherein the parameters of the sub-neural network 300 are a subset of the parameters of the sub-neural network 200, and the parameters of the sub-neural network 200 are a subset of the parameters of the main neural network 100. The neural networks in the group of neural networks may be said to be nested within each other; i.e. the sub-neural network 300 is nested within the sub-neural network 200, and the sub-neural network 200 is nested within the main neural network 100. This “nesting” is indicated by way of the vertical arrows in FIG. 5 between the sub-neural network 300, the sub-neural network 200 and the main neural network 100.

The main neural network 100 illustrated in FIG. 5 is only one example of a group of neural networks in accordance with the present disclosure, and other groups of neural networks may alternatively be provided. As used herein, the term “sub-neural network” in relation to the main neural network defines a neural network having one or more parameters, i.e. trainable parameters, that are shared by the neural network and the main neural network. In other words, one or more of the parameters of each sub-neural network are shared by the sub-neural network and the main neural network.

Thus, variations of the example group of neural networks illustrated in FIG. 5 are also contemplated. Examples are contemplated wherein one or more of the parameters of each sub-neural network 200 and 300 are shared by the respective sub-neural network and the main neural network. Furthermore, rather than all of the parameters of a sub-neural network being a subset of the parameters of another sub-neural network, as in “nested” neural networks 200, 300, none, or one or more parameters of a sub-neural network may be shared by the sub-neural network and another sub-neural network.

In one example, each neural network 100, 200, 300 in the group of neural networks comprises a separate output. In one example, a group of neural networks is provided wherein the parameters of the lowest neural network in the group of neural networks are shared by all neural networks in the group of neural networks.

The group of neural networks may be identified in operation S100 in various ways. In some examples the group of neural networks are identified from a plurality of neural networks. The plurality of neural networks may include a set of neural networks. Thus the identifying may include identifying the neural networks from the set, or “pool” of neural networks. In some examples, a group of neural networks is identified in operation S100 by providing a main neural network 100, and providing the sub-neural networks from one or more portions of the main neural network. For example, a complete CNN operating on a 16×16 image with 3 channels (RGB) with a hidden layer having 10 channels followed by a global pooling operation and a Softmax output layer might serve as the main neural network. A first sub-neural network might be provided by the first 4 channels of the hidden layer of the main neural network, and with its outputs taken from the Softmax output layer of the main neural network where zeros are used for the inputs of channels not present. Likewise, a second sub-neural network might be provided by a different set of 4 channels from the hidden layer of the main neural network, and its outputs taken from the Softmax output layer of the main neural network where zeros are used for the inputs of channels not present. In so doing, it is arranged that the parameters of each sub-neural network are shared by the sub-neural network and the main neural network.

In some examples, a group of neural networks is identified in operation S100 by augmenting an initial sub-neural network with additional neurons in existing and/or additional layers to arrive at a main neural network wherein some of the neurons in the initial sub-neural network are shared by the sub-neural network and the main neural network.

In some examples, a group of neural networks is identified in operation S100 by performing a neural architecture search. Various neural architecture search techniques may be employed, including but not limited to random search, simulated annealing, evolutionary methods, proxy neural architecture search, differentiable neural architecture search and so forth. When a differential neural architecture search is employed, the performance scores computed in operation S130 may be approximated for the respective hardware environment by using a differentiable performance model for each neural network. Differentiable performance models may for example be provided by training a second neural network to estimate a performance score of each neural network in the group of neural networks. A neural architecture search technique may be used to identify the main neural network and the sub-neural networks from a search space of neural networks or portions of neural networks. The identifying operation S100 may alternatively or additionally include maximizing a count of the number of parameters that are shared between the neural networks in the group of neural networks. Maximizing the count of the number of shared parameters may reduce the size of the neural networks in the group of neural networks. Operation S100 may optionally include adjusting the hyperparameters of the neural network in order to try to select better values.

Examples of groups of neural networks are contemplated that have different numbers of sub-neural networks, different numbers of layers in the neural networks, different layer connectivity in the neural networks, and neural networks with a different architecture, to the example group of neural networks illustrated in FIG. 5. The neural networks may in general be selected from a range of available neural networks having the same, or different architectures. The neural networks may for example be selected from a search space of neural networks having a CNN, an RNN, an GAN, an Autoencoder architecture, and so forth, and are not limited to the Deep Feed Forward architecture illustrated in FIG. 5.

Returning to the method of FIG. 3, the method continues from the identifying operation S100, with operation S110, wherein training data 400 is inputted into each neural network 100, 200, 300 in the group of neural networks. In operation S120, the parameters of each neural network 100, 200, 300, i.e. the trainable parameters, are adjusted using an objective function 410 that is computed based on a difference between output data generated at an output 110, 210, 310 of each neural network 100, 200, 300, and expected output data 420. Using the example of a neural network that performs a classification task, the expected output data 420 may represent a label of the training data, and together the operations S110 and S120 train each neural network 100, 200, 300, to a certain extent, to classify the training data.

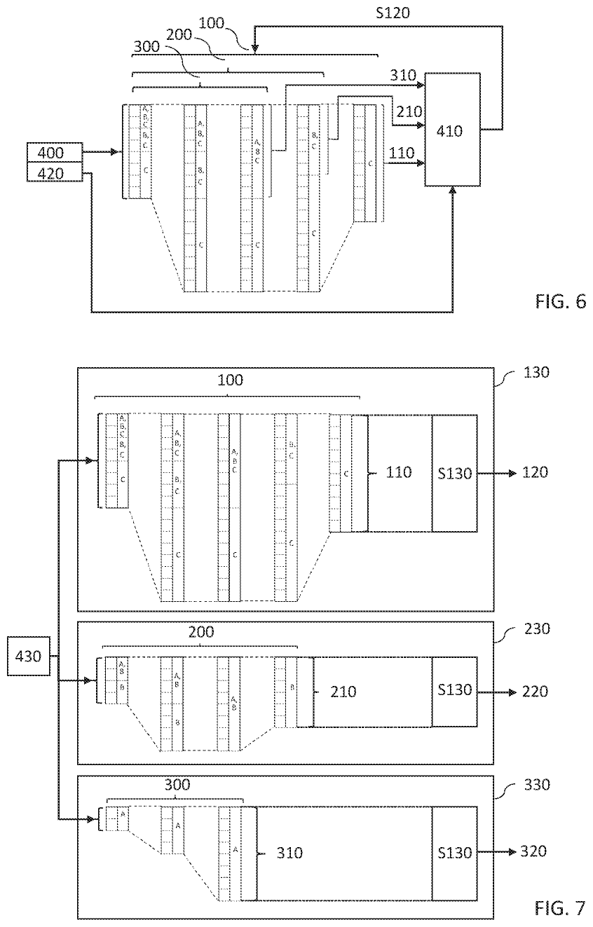

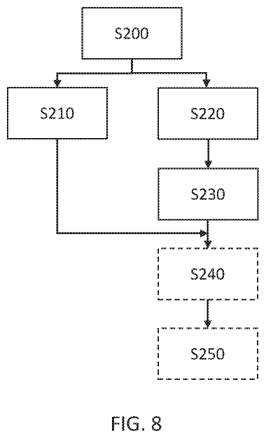

The operations S110 and S120 are now described with reference to FIG. 6, which is a schematic diagram illustrating an example of inputting S110 training data and adjusting S120 parameters of each neural network using an objective function 410, in accordance with some aspects of the present disclosure. FIG. 6 includes the main neural network 100 illustrated in the upper portion of FIG. 5, and which includes sub-neural networks 200 and 300. As illustrated towards the left side of FIG. 6, in operation S110, training data 400 is inputted into each of main neural network 100 and sub neural networks 200, 300. Output data from each neural network is generated respectively at outputs 110, 210, 310. The objective function 410 determines a difference between output data generated at an output 110, 210, 310 of each neural network 100, 200, 300, and expected output data 420. The objective function may be provided by various functions, including for example the mean squared error, the Huber loss, or the cross entropy. In operation S120, the parameters of each neural network 100, 200, 300 may be adjusted using the value of the objective function by means of backpropagation. The parameters are typically adjusted so as to minimize the value of the objective function. Various algorithms are known for use in backpropagation, including Stochastic Gradient Descent “SGD”, Momentum, Adam, Nadam, Adagrad, Adadelta, RMSProp, and Adamax.

In some examples, the adjusting operation S120 is performed by simultaneously adjusting the parameters of each neural network 100, 200, 300 in successive iterations. In some examples the adjusting operation S120 is performed by adjusting the parameters of each neural network 100, 200, 300 in successive iterations i) until a value of the objective function 410 satisfies a stopping criterion, or ii) for a predetermined number of iterations. The stopping criterion may for example be that the value of the objective function 410 is within a predetermined range. The predetermined range indicates that each of the neural networks 100, 200, 300 in the group of neural networks has been trained to a certain extent. The training may be partial or full. The value of the objective function resulting from partial training may give an indication of the ability of the neural network to be trained with the training data. Full training clearly takes more time, and the value of the objective function resulting from full training gives an indication of the ultimate accuracy of the trained neural network.

In some examples, the objective function 410 is computed based further on a difference between the output data generated at the outputs 110, 210, 310 of each neural network 100, 200, 300 in the group of neural networks. Using this difference as an additional constraint to guide the adjustment of the parameters of the neural networks may result in a reduced number of parameters in the trained neural network and/or a reduction in latency when performing inference. A difference between the outputs of the neural networks may be determined using functions such as the mean squared error, the Huber loss, or the cross entropy.

Returning to FIG. 3, the method continues with operation S130, wherein a performance score 120, 220, 320 is computed for each neural network 100, 200, 300 in the group of neural networks using the adjusted parameters. The adjusted parameters are the parameters that result from the adjusting operation S120 and represent the partially, or fully-trained parameters of each neural network. The performance score represents a performance of each neural network 100, 200, 300 in a respective hardware environment 130, 230, 330. The hardware environment represents a processor and/or a memory in which inference may be performed. The hardware environment may be defined by technical characteristics such as an amount and type of memory, a number of processor cores, a processing speed, whether floating point processing is supported, and so forth. One example of a hardware environment is the Arm Cortex-M55, which features Arm Helium vector processing technology, compared to the Arm Cortex-M7, which does not. Another example of a hardware environment is the Arm Cortex-A55, which supports up to 8 cores with 4 MB of shared L3 cache, compared to the Arm Cortex-M55's single core with up to 64 KB of data cache.

By way of some non-limiting examples, the performance score may be computed based on one or more of:
a count of the number of parameters shared by the neural networks 100, 200, 300 in the group of neural networks;
a latency of the respective neural network 100, 200, 300 in processing test data 430 in the respective hardware environment 130, 230, 330;
a processing utilization of the respective neural network 100, 200, 300 in processing test data 430 in the respective hardware environment 130, 230, 330;
a flop count, i.e. the number of floating point operations per second, of the respective neural network 100, 200, 300 in processing test data 430 in the respective hardware environment 130, 230, 330;
a working memory utilization of the respective neural network 100, 200, 300 in processing test data 430 in the respective hardware environment 130, 230, 330;
a memory bandwidth utilization of the respective neural network 100, 200, 300 in processing test data 430 in the respective hardware environment 130, 230, 330;
an energy consumption utilization of the respective neural network 100, 200, 300 in processing test data 430 in the respective hardware environment 130, 230, 330;
a compression ratio of the respective neural network 100, 200, 300 in the respective hardware environment 130, 230, 330.

In one example, computing a performance score 120, 220, 320 for each neural network 100, 200, 300 in the group of neural networks using the adjusted parameters, comprises: applying a model of the respective hardware environment 130, 230, 330 to each neural network 100, 200, 300 during the generation of output data in response to the inputting S110 training data 400. In this example, a model that applies a processing time to each parameter or neuron in each neural network may be used to estimate the latency of generating an output from the neural network in response to input data. The model may likewise apply a memory utilization to the processing of each parameter or neuron in the neural network in order to estimate the memory requirement of each neural network. A low latency and/or a low memory utilization may be associated with high performance.

In another example, computing a performance score 120, 220, 320 for each neural network 100, 200, 300 in the group of neural networks using the adjusted parameters, comprises: inputting test data 430 to each neural network 100, 200, 300 in a simulation of the respective hardware environment 130, 230, 330. This is illustrated with reference to FIG. 7, which is a schematic diagram illustrating an example of computing S130 a performance score 120, 220, 320 for a main neural network and for each of two sub-neural networks 200, 300 by inputting test data 430 to each neural network 100, 200, 300 in a simulation of a respective hardware environment 130, 230, 330, in accordance with some aspects of the present disclosure. FIG. 7 illustrates each of hardware environments 130, 230, 330, and the inputting of test data 430 into each of main neural network 100 and sub-neural networks 200, 300 in the respective hardware environments to generate respective performance scores 120, 220, 330. In this example, the simulation may for example restrict the amount of memory and/or number of processor cores available to the neural network to those available in each hardware environment, and thereby arrive at a performance score such as the latency, of the neural network in the respective hardware environment.

In some examples, the performance score is used to compute the above-mentioned objective function 410. In these examples, the performance score 120, 220, 320 may therefore impact the adjustment of the parameters of each neural network 100, 200, 300 in operation 120. In these examples, adjusting the parameters of each neural network 100, 200, 300 in operation S120 comprises adjusting the parameters in successive iterations, and computing a performance score 120, 220, 320 for each neural network 100, 200, 300 in each iteration. The objective function 410 is computed at each iteration based further on the performance scores 120, 220, 320 of each neural network 100, 200, 300 in the group of neural networks using the adjusted parameters. This is indicated by way of the dashed arrow in FIG. 3, wherein after having computed the performance score and incorporated its value into the objective function 410, the value of the objective function is used to adjust the parameters of each neural network. A performance score representing for example latency, might for example be incorporated into the objective function so as to penalize high latency by causing high latency to increase the output of the objective function 410. As mentioned above, in operation S120, the parameters of each neural network are typically adjusted so as to minimize the value of the objective function. The adjusting of the parameters of each neural network 100, 200, 300 in operation S120 therefore attempts to reduce the value of the objective function 410, and thus adjusts the parameters so as to reduce the latency. The incorporation of the performance score into the objective function 410 in this manner helps improve the training of each neural network for its respective hardware environment.

Irrespective of whether the performance score is used to compute the above-mentioned objective function 410, or not, the method illustrated in FIG. 3 continues with operation S140, wherein a combined score is generated for the group of neural networks by combining the performance score 120, 220, 320 of each neural network 100, 200, 300 in the group of neural networks, with a value of a loss function computed for each neural network 100, 200, 300 in the group of neural networks using the adjusted parameters. The combined score provides an indication of the overall suitability of the neural networks 100, 200, 300 in the group of neural networks for processing the training data across the range of hardware environments 130, 230, 330. The combined score may for example be generated by summing the performance score and the value of the loss function. The performance score and the value of the loss function may alternatively be combined in other ways, such as by multiplying their values, and so forth. By way of an example, the hardware environments may include an ARM M-class processor such as the Arm Cortex-M55, an ARM A-class processor such as the Arm Cortex-A78, and an “NPU” such as the Arm Ethos-U55. The combined score provides an indication of the overall suitability of the neural networks 100, 200, 300 for processing the training data across the range of hardware environments.

The value of the loss function may be computed for each neural network 100, 200, 300 in the group of neural networks:
i) based on the difference between the output data generated at the output 110, 210, 310 of each neural network 100, 200, 300, and the expected output data 420; and/or
ii) based on a difference between output data generated at the output 110, 210, 310 of each neural network 100, 200, 300 in response to inputting test data 430 into the neural network, and desired output data.

In the case of a neural network that performs a classification task, the value of the loss function represents the accuracy of the neural network. The combined score, together with the parameters of the group of neural networks may be stored, for example in the non-transitory computer-readable storage media 560 illustrated in FIG. 4.

Returning to FIG. 3, the method continues with operation S150, wherein the identifying operation S100 and the inputting operation S110 and the adjusting operation S120 and the computing operation S130 and the generating S140 operation, are repeated for two or more iterations. The repeating may for example be performed for less than ten, or for tens, or for hundreds, or for thousands, or more, iterations. In some examples, the repeating operation S150 is performed for a predetermined number of iterations. In other examples, the repeating operation S150 is performed until the combined score for the group of neural networks that is determined in operation S140, satisfies a predetermined condition. The predetermined condition may for example be that the combined score exceeds or is less than a predetermined value, or is within a predetermined range. In so doing, it is provided that the neural networks in at least one of the groups of neural networks generated by the repeating operation S150, are sufficiently suitable for processing the training data across the range of hardware environments 130, 230, 330.

With continued reference to FIG. 3, the method continues with operation S160, which includes selecting S160 from the plurality of groups of neural networks generated by the repeating S150, a group of neural networks for processing data in the plurality of hardware environments 130, 230, 330 based on the value of the combined score for each group of neural networks. As mentioned above, the combined score provides an indication of the overall suitability of the neural networks 100, 200, 300 in the group of neural networks for processing the training data across the range of hardware environments. In some examples, a high combined score correlates with high suitability, and thus the group of networks with the highest combined score may be selected in the operation S160. In other examples, a low combined score correlates with high suitability, and thus the group of networks with the lowest combined score may be selected in the operation S160. In so doing, the most suitable group of neural networks for processing the training data across the range of hardware environments, is provided.

Examples of a group of neural networks that are provided in the above manner mitigate the risk of poor neural network performance due to a mismatch between the targeted inference hardware environment and the actual inference hardware environment. Inference may be improved in an actual hardware environment by using such an example group of neural networks because the group of neural networks includes neural networks that are suited to different hardware environments. A client device may therefore select a neural network from the group of neural networks that is most suited to the actual hardware environment in which inference is performed. Moreover, in such examples, since the neural networks in the group of neural networks include shared parameters, the size of the group of neural networks, and their training burden, may be reduced in comparison to neural networks that have completely independent parameters.

As illustrated in FIG. 3 by way of the dashed outlines, the above method may optionally continue with operation S170. Depending on how many iterations of the adjusting parameters of each neural network are performed in operations S110 and S120 above, the neural networks in the group of neural networks provided by operation S160 may be partially or fully-trained. Additional training may be provided in operation S170 to further optimize the parameters of each neural network. Operation S170 includes training S170 each neural network 100, 200, 300 in the selected group of neural networks for processing data in the respective hardware environment 130, 230, 330 by inputting second training data into each neural network 100, 200, 300 in the group of neural networks, and adjusting the parameters of each neural network 100, 200, 300 using a second objective function computed based on a difference between output data generated at an output 110, 210, 310 of each neural network 100, 200, 300, and expected output data. If the neural networks in the group of neural networks are designed to perform a classification task, the expected output data may represent a label of the second training data.

As illustrated in FIG. 3 by way of the dashed outlines, the above method may also optionally continue with operation S180, and wherein the selected group of neural networks is deployed. With reference to FIG. 4, the operations of identifying S100, inputting S110, adjusting S120, computing S130, generating S140, repeating S150 and selecting S160, may be performed by a first processing system 550, and in operation S180, the selected group of neural networks is deployed to a second processing system 650_{1.k}. The group of neural networks may optionally be compressed prior to their deployment in operation S180. The deployment of the selected group of neural networks in operation S180 may take place by any means of data communication, including via wired or wireless data communication, and may for example be via the internet, an ethernet, or by transferring the data by means of a portable computer-readable storage medium such as a USB memory device, an optical or magnetic disk, and so forth. The second processing system 650_{1.k} may then be used to perform inference on new data with one or more of the neural networks from the deployed group of neural networks.

The first processing system 550 illustrated in FIG. 4 may for example be a cloud-based processing system or a server-based processing system or a mainframe-based processing system, and in some examples its one or more processors may include one or more neural processors or neural processing units “NPU”, one or more CPUs or one or more GPUs. It is also contemplated that the first processing system 550 may be provided by a distributed computing system. The first processing system may be in communication with one or more non-transitory computer-readable storage media 560, which collectively store instructions for performing the method, data representing the groups of neural networks generated by the method, their parameter values, their combined scores, training data 400, expected output data 420 from the training data, second training data, expected output data from the second training data, test data 430, and so forth.

The second processing system 650_{1 . . . k} illustrated in FIG. 4 may comprise one or more processors. The one or more processors may be in communication with one or more non-transitory computer readable storage media 660_{1 . . . k}. The one or more non-transitory computer readable storage media 660_{1 . . . k} collectively store instructions for performing a further method described below, and may also store data representing a group of neural networks deployed by the first processing system, its parameter values, and so forth. Each second processing system 650_{1 . . . k} may form part of a device 600_{1 . . . k}, which may be a client device as described in more detail below.

The lower portion of FIG. 4 illustrates multiple devices 600_{1 . . . k} that may be in communication with the system 500. Each device 600_{1 . . . k} may for example be a client device or a remote device or a mobile device. Each device 600_{1 . . . k} may for example be a so-called edge computing device or an Internet of Things “IOT” device, such as a laptop computer, a tablet, a mobile telephone, or a “smart appliance” such as a smart doorbell, a smart fridge, a home assistant, a security camera, a sound detector, or a vibration detector, or an atmospheric sensors, or an “autonomous device” such as a vehicle, or a drone, or a robot and so forth. The communication between each device 600_{1 . . . k} and the system 500 may be via any means of data communication, including via wired or wireless data communication, and may be via the internet, an ethernet and so forth. As mentioned above, each device 600_{1 . . . k} includes a second processing system 650_{1 . . . k}, and may also include one or more non-transitory computer readable storage media 660_{1 . . . k}.

Each device 600_{1 . . . k} is suitable for identifying a neural network for processing data in a hardware environment, and each device comprises a second processing system 650 comprising one or more processors configured to carry out a method comprising:
i) receiving S200 a group of neural networks provided according to the above method, the group of neural networks including metadata representing a target hardware environment 130, 230, 330 and/or a hardware requirement, of each neural network 100, 200, 300 in the group of neural networks; and
selecting S210, based on the metadata, a neural network from the group of neural networks to process data;
or
ii) receiving S200 a group of neural networks provided according to the above method;
computing S220 a performance score for one or more neural networks in the group of neural networks based on an output of the respective neural network generated in response to inputting test data 430 into the respective neural network and processing the test data 430 with the respective neural network in the hardware environment 130, 230, 330; and
selecting S230 a neural network from the group of neural networks to process data based on a value of the performance score.

Thus, in i) the metadata is used by the second processing system 650 to select the most suitable neural network from the group of neural networks, for processing data in the hardware environment of the second processing system 650. In ii) a performance score is computed by the second processing system 650 in order to select the most suitable neural network from the group of neural networks, for processing data in the hardware environment of the second processing system 650. The performance score may for example be one of the performance scores mentioned above.

The second processing system 650_{1 . . . k} of the device 600_{1 . . . k} may then be used to process new input data with the selected neural network in the hardware environment of the second processing system 650_{1 . . . k}. The new data processed by the second processing system 650_{1 . . . k} may be any type of data, such as image data and/or audio data and/or vibration data and/or video data and/or text data and/or LiDAR data, and/or numerical data. The new data may be received via any form of data communication, such as wired or wireless data communication, and may be via the internet, an ethernet, or by transferring the data by means of a portable computer-readable storage medium such as a USB memory device, an optical or magnetic disk, and so forth. In some examples the data is received from a sensor such as a camera, a microphone, a motion sensor, a temperature sensor, a vibration sensor, and so forth. In some examples the sensor may be included within the device 600_{1 . . . k}.

Each device 600_{1 . . . k} may therefore execute a computer-implemented method of identifying a neural network for processing data in a hardware environment, the method comprising:
i) receiving S200 a group of neural networks provided according to the method of claim 1, the group of neural networks including metadata representing a target hardware environment 130, 230, 330 and/or a hardware requirement, of each neural network 100, 200, 300 in the group of neural networks; and
selecting S210, based on the metadata, a neural network from the group of neural networks to process data;

or
ii) receiving S200 a group of neural networks provided according to the method of claim 1; and
computing S220 a performance score for one or more neural networks in the group of neural networks based on an output of the respective neural network generated in response to inputting test data 430 into the respective neural network and processing the test data 430 with the respective neural network in the hardware environment 130, 230, 330; and
selecting S230 a neural network from the group of neural networks to process data based on a value of the performance score.

In some examples, the method carried out by the device 600_{1 . . . k} may also include:
processing S240 input data with the selected neural network in the hardware environment 130, 230, 330, and dynamically shifting S250 a processing of the input data by the neural network between a plurality of processors of the hardware environment 130, 230, 330 responsive a performance score computed for the processing meeting a specified condition.

In so doing, more optimal use of the processing capability of the device 600_{1 . . . k} may be achieved.

Examples of the above-described method carried out by the device 600_{1 . . . k}, or the method carried out by the system 500, may be provided by a non-transitory computer-readable storage medium comprising a set of computer-readable instructions stored thereon which, when executed by at least one processor, cause the at least one processor to perform the method. In other words, examples of the above-described methods may be provided by a computer program product. The computer program product can be provided by dedicated hardware or hardware capable of running the software in association with appropriate software. When provided by a processor, these operations can be provided by a single dedicated processor, a single shared processor, or multiple individual processors that some of the processors can share. Moreover, the explicit use of the terms “processor” or “controller” should not be interpreted as exclusively referring to hardware capable of running software, and can implicitly include, but is not limited to, digital signal processor “DSP” hardware, GPU hardware, NPU hardware, read only memory “ROM” for storing software, random access memory “RAM”, NVRAM, and the like. Furthermore, implementations of the present disclosure can take the form of a computer program product accessible from a computer usable storage medium or a computer readable storage medium, the computer program product providing program code for use by or in connection with a computer or any instruction execution system. For the purposes of this description, a computer-usable storage medium or computer-readable storage medium can be any apparatus that can comprise, store, communicate, propagate, or transport a program for use by or in connection with an instruction execution system, apparatus, or device. The medium can be an electronic, magnetic, optical, electromagnetic, infrared, or semiconductor system or device or device or propagation medium. Examples of computer readable media include semiconductor or solid state memories, magnetic tape, removable computer disks, random access memory “RAM”, read only memory “ROM”, rigid magnetic disks, and optical disks. Current examples of optical disks include compact disk-read only memory “CD-ROM”, optical disk-read/write “CD-R/W”, Blu-Ray™, and DVD.

The above examples are to be understood as illustrative of the present disclosure. Further implementations are also envisaged. For example, implementations described in relation to a method may also be implemented in a computer program product, in a computer readable storage medium, in a system, or in a device. It is therefore to be understood that a feature described in relation to any one implementation may be used alone, or in combination with other features described, and may also be used in combination with one or more features of another of the implementation, or a combination of other the implementations. Furthermore, equivalents and modifications not described above may also be employed without departing from the scope of the disclosure, which is defined in the accompanying claims. Any reference signs in the claims should not be construed as limiting the scope of the disclosure.

What is claimed is:

1. A computer-implemented method of providing a group of neural networks for processing data in a plurality of hardware environments, the method comprising:
identifying (S100) a group of neural networks including a main neural network (100) and one or more sub-neural networks (200, 300), each neural network (100, 200, 300) in the group of neural networks comprising a plurality of parameters and wherein one or more of the parameters of each sub-neural network are shared by the sub-neural network and the main neural network (100);
inputting (S110) training data (400) into each neural network (100, 200, 300) in the group of neural networks, and adjusting (S120) the parameters of each neural network (100, 200, 300) using an objective function (410) computed based on a difference between output data generated at an output (110, 210, 310) of each neural network (100, 200, 300), and expected output data (420);
computing (S130) a performance score (120, 220, 320) for each neural network (100, 200, 300) in the group of neural networks using the adjusted parameters, the performance score representing a performance of each neural network (100, 200, 300) in a respective hardware environment (130, 230, 330);
generating (S140) a combined score for the group of neural networks by combining the performance score (120, 220, 320) of each neural network (100, 200, 300) in the group of neural networks, with a value of a loss function computed for each neural network (100, 200, 300) in the group of neural networks using the adjusted parameters;
repeating (S150) the identifying (S100) and the inputting (S110) and the adjusting (S120) and the computing (S130) and the generating (S140), for two or more iterations; and
selecting (S160) from the plurality of groups of neural networks generated by the repeating (S150), a group of neural networks for processing data in the plurality of hardware environments (130, 230, 330) based on the value of the combined score for each group of neural networks.

2. The computer-implemented method according to claim 1, wherein the adjusting (S120) the parameters of each neural network (100, 200, 300) comprises adjusting the parameters in successive iterations, and wherein the computing (S130) a performance score (120, 220, 320) for each neural network (100, 200, 300) is performed in each iteration, and wherein the objective function (410) is computed at each iteration based further on the performance scores (120, 220, 320) of each neural network (100, 200, 300) in the group of neural networks using the adjusted parameters.

3. The computer-implemented method according to claim 1, wherein the adjusting (S120) the parameters of each neural network (100, 200, 300), is performed by simultaneously adjusting the parameters of each neural network (100, 200, 300) in successive iterations.

4. The computer-implemented method according to claim 1, wherein the adjusting (S120) the parameters of each neural network (100, 200, 300) is performed by adjusting the parameters of each neural network (100, 200, 300) in successive iterations i) until a value of the objective function (410) satisfies a stopping criterion, or ii) for a predetermined number of iterations.

5. The computer-implemented method according to claim 1, wherein the objective function (410) is computed based further on a difference between the output data generated at the outputs (110, 210, 310) of each neural network (100, 200, 300) in the group of neural networks.

6. The computer-implemented method according to claim 1, wherein the performance score (120, 220, 320) for each neural network (100, 200, 300) in the group of neural networks is computed based on one or more of:
a count of the number of parameters shared by the neural networks (100, 200, 300) in the group of neural networks;
a latency of the respective neural network (100, 200, 300) in processing test data (430) in the respective hardware environment (130, 230, 330);
a processing utilization of the respective neural network (100, 200, 300) in processing test data (430) in the respective hardware environment (130, 230, 330);
a flop count of the respective neural network (100, 200, 300) in processing test data (430) in the respective hardware environment (130, 230, 330);
a working memory utilization of the respective neural network (100, 200, 300) in processing test data (430) in the respective hardware environment (130, 230, 330);
a memory bandwidth utilization of the respective neural network (100, 200, 300) in processing test data (430) in the respective hardware environment (130, 230, 330);
an energy consumption utilization of the respective neural network (100, 200, 300) in processing test data (430) in the respective hardware environment (130, 230, 330);
a compression ratio of the respective neural network (100, 200, 300) in the respective hardware environment (130, 230, 330).

7. The computer-implemented method according to claim 1, wherein the computing (S130) a performance score (120, 220, 320) for each neural network (100, 200, 300) in the group of neural networks using the adjusted parameters, comprises:
applying a model of the respective hardware environment (130, 230, 330) to each neural network (100, 200, 300) during the generation of output data in response to the inputting (S110) training data (400); and/or
inputting test data (430) to each neural network (100, 200, 300) in a simulation of the respective hardware environment (130, 230, 330).

8. The computer-implemented method according to claim 1, wherein the value of the loss function is computed for each neural network (100, 200, 300) in the group of neural networks:
i) based on the difference between the output data generated at the output (110, 210, 310) of each neural network (100, 200, 300), and the expected output data (420); and/or
ii) based on a difference between output data generated at the output (110, 210, 310) of each neural network (100, 200, 300) in response to inputting test data (430) into the neural network, and desired output data.

9. The computer-implemented method according to claim 1, comprising:
training (S170) each neural network (100, 200, 300) in the selected group of neural networks for processing data in the respective hardware environment (130, 230, 330) by inputting second training data into each neural network (100, 200, 300) in the group of neural networks, and adjusting the parameters of each neural network (100, 200, 300) using a second objective function computed based on a difference between output data generated at an output (110, 210, 310) of each neural network (100, 200, 300), and expected output data.

10. The computer-implemented method according to claim 1, wherein the parameters of the lowest neural network in each group of neural networks are shared by all neural networks in the group of neural networks.

11. The computer-implemented method according to claim 1, wherein the identifying (S100) comprises providing a main neural network (100), and providing each of the one or more sub-neural networks (200, 300) from one or more portions of the main neural network (100).

12. The computer-implemented method according to claim 1, wherein the identifying (S100) comprises performing a neural architecture search and/or wherein the identifying comprises maximizing a count of the number of parameters that are shared between the neural networks in the group of neural networks.

13. The computer-implemented method according to claim 1, wherein the operations of identifying (S100), inputting (S110), adjusting (S120), computing (S130), generating (S140), repeating (S150) and selecting (S160), are performed by a first processing system (550), and comprising deploying (S180) the selected group of neural networks to a second processing system (650).

14. The computer-implemented method according to claim 1, wherein the repeating (S150) comprises i) performing the repeating (S150) for a predetermined number of iterations or ii) performing the repeating until the combined score for the group of neural networks satisfies a predetermined condition.

15. A computer-implemented method of identifying a neural network for processing data in a hardware environment, the method comprising:
i) receiving (S200) a group of neural networks provided according to the method of claim 1, the group of neural networks including metadata representing a target hardware environment (130, 230, 330) and/or a hardware requirement, of each neural network (100, 200, 300) in the group of neural networks; and
selecting (S210), based on the metadata, a neural network from the group of neural networks to process data;
or
ii) receiving (S200) a group of neural networks provided according to the method of claim 1; and
computing (S220) a performance score for one or more neural networks in the group of neural networks based on an output of the respective neural network generated in response to inputting test data (430) into the respective neural network and processing the test data (430) with the respective neural network in the hardware environment (130, 230, 330); and
selecting (S230) a neural network from the group of neural networks to process data based on a value of the performance score.

16. The computer-implemented method according to claim 15, comprising processing (S240) input data with the selected neural network in the hardware environment (130, 230, 330), and dynamically shifting (S250) a processing of the input data by the neural network between a plurality of processors of the hardware environment (130, 230, 330) responsive a performance score computed for the processing meeting a specified condition.

17. The computer-implemented method according to claim 1, wherein the identifying (S100) a group of neural networks comprises:
i) performing a neural architecture search; or
ii) performing a differential neural architecture search; and wherein the computing (S130) a performance score (120, 220, 320) for each neural network (100, 200, 300) in the group of neural networks, comprises approximating a performance score (120, 220, 320) for each neural network (100, 200, 300) in the group of neural networks for the respective hardware environment (130, 230, 330) using a differentiable performance model for each neural network (100, 200, 300).

18. A system (500) for providing a group of neural networks for processing data in a plurality of hardware environments, the system comprising a first processing system (550) comprising one or more processors configured to carry out a method comprising:
identifying (S100) a group of neural networks including a main neural network (100) and one or more sub-neural networks (200, 300), each neural network (100, 200, 300) in the group of neural networks comprising a plurality of parameters and wherein one or more of the parameters of each sub-neural network are shared by the sub-neural network and the main neural network (100);
inputting (S110) training data (400) into each neural network (100, 200, 300) in the group of neural networks, and adjusting (S120) the parameters of each neural network (100, 200, 300) using an objective function (410) computed based on a difference between output data generated at an output (110, 210, 310) of each neural network (100, 200, 300), and expected output data (420);
computing (S130) a performance score (120, 220, 320) for each neural network (100, 200, 300) in the group of neural networks using the adjusted parameters, the performance score representing a performance of each neural network (100, 200, 300) in a respective hardware environment (130, 230, 330);
generating (S140) a combined score for the group of neural networks by combining the performance score (120, 220, 320) of each neural network (100, 200, 300) in the group of neural networks, with a value of a loss function computed for each neural network (100, 200, 300) in the group of neural networks using the adjusted parameters;
repeating (S150) the identifying (S100) and the inputting (S110) and the adjusting (S120) and the computing (S130) and the generating (S140), for two or more iterations; and
selecting (S160) from the plurality of groups of neural networks generated by the repeating (S150), a group of neural networks for processing data in the plurality of hardware environments (130, 230, 330) based on the value of the combined score for each group of neural networks.

19. A device (600_{1 . . . k}) for identifying a neural network for processing data in a hardware environment, the device comprising a second processing system (650_{1 . . . k}) comprising one or more processors configured to carry out a method comprising:
i) receiving (S200) a group of neural networks provided according to the method of claim 1, the group of neural networks including metadata representing a target hardware environment (130, 230, 330) and/or a hardware requirement, of each neural network (100, 200, 300) in the group of neural networks; and
selecting (S210), based on the metadata, a neural network from the group of neural networks to process data;
or
ii) receiving (S200) a group of neural networks provided according to the method of claim 1;
computing (S220) a performance score for one or more neural networks in the group of neural networks based on an output of the respective neural network generated in response to inputting test data (430) into the respective neural network and processing the test data (430) with the respective neural network in the hardware environment (130, 230, 330); and
selecting (S230) a neural network from the group of neural networks to process data based on a value of the performance score.

20. A non-transitory computer-readable storage medium comprising instructions which when executed by one or more processors cause the one or more processors to carry out the method according to claim 15.
